(19) United States
(12) Patent Application Publication
(10) Pub. No.: US 2023/0077958 A1
(43) Pub. Date: Mar. 16, 2023

(54) OPTICAL TRANSMISSION MODULE

(71) Applicant: SUMITOMO ELECTRIC INDUSTRIES, LTD., Osaka (JP)

(72) Inventors: Kosuke OKAWA, Osaka (JP); Hiroshi HARA, Osaka (JP); Naoki ITABASHI, Osaka (JP)

(21) Appl. No.: 17/930,126

(22) Filed: Sep. 7, 2022

(30) Foreign Application Priority Data
Sep. 10, 2021 (JP) 2021-147874

(51) Int. Cl. H01S 5/024; H01S 5/02253; H04B 10/50

(52) U.S. Cl. CPC H01S 5/02469; H01S 5/02253; H04B 10/501

(57) ABSTRACT

An optical transmission module includes a metal base including a signal terminal which extends along a first direction, a dielectric block including a dielectric substance, the dielectric block having a semiconductor plane, an optical plane, and a thermal plane, the semiconductor plane and the optical plane being parallel to the first direction, the thermal plane crossing the first direction, and the semiconductor plane being provided between the optical plane and the thermal plane in the first direction, an optical semiconductor element mounted on the semiconductor plane, the optical semiconductor element being electrically connected with the signal terminal, a temperature regulating element provided between the dielectric block and the metal base in the first direction, the temperature regulating element being contacted with the thermal plane, and a lens mounted on the optical plane.

### CROSS-REFERENCE TO RELATED APPLICATIONS

This application claims priority from Japanese Patent Application No. 2021-147874, filed on Sep. 10, 2021, the entire subject matter of which is incorporated herein by reference.

### BACKGROUND

### 1. Field of the Invention

The present disclosure relates to an optical transmission module.

### 2. Description of the Related Art

Japanese Unexamined Patent Application Publication No. 2011-197360 discloses a semiconductor light modulation device in which a semiconductor light modulation element is disposed on a temperature control module mounted on a metal base. This publication discloses that a capacitor is connected to a signal line, and the value of the capacitor is set so as to perform impedance matching in the semiconductor light modulation element.

WO 2010/140473 A1 discloses a semiconductor light modulation device in which a bonding wire is connected between each of a lead pin, a signal line, a signal conductor, and a semiconductor light modulation element.

Japanese Unexamined Patent Application Publication No. 2020-098837 discloses an optical subassembly including a spacer for electrically connecting a back surface of a relay board and a pedestal.

### SUMMARY

An optical transmission module includes a metal base including a signal terminal which extends along a first direction, a dielectric block including a dielectric substance, the dielectric block having a semiconductor plane, an optical plane, and a thermal plane, the semiconductor plane and the optical plane being parallel to the first direction, the thermal plane crossing the first direction, and the semiconductor plane being provided between the optical plane and the thermal plane in the first direction, an optical semiconductor element mounted on the semiconductor plane, the optical semiconductor element being electrically connected with the signal terminal, a temperature regulating element provided between the dielectric block and the metal base in the first direction, the temperature regulating element being contacted with the thermal plane, and a lens mounted on the optical plane.

### BRIEF DESCRIPTION OF THE DIAGRAMS

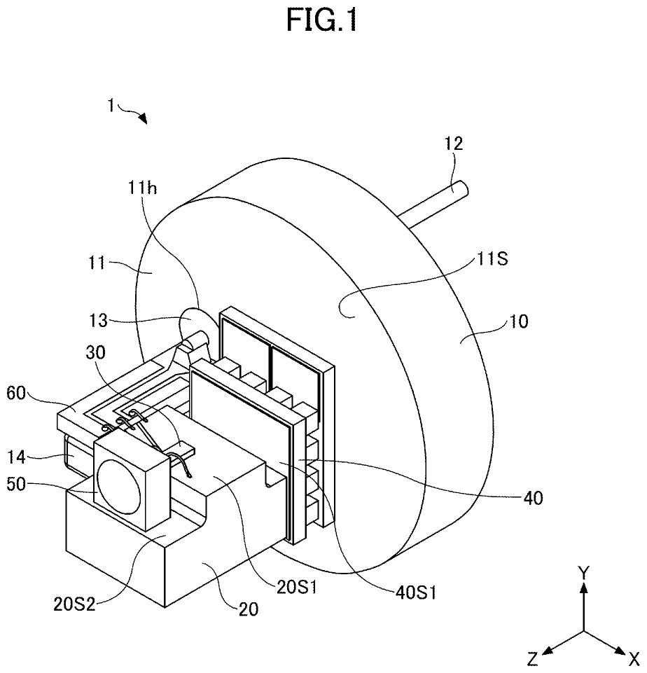

FIG. 1 is a perspective view of an optical transmission module according to a first embodiment;

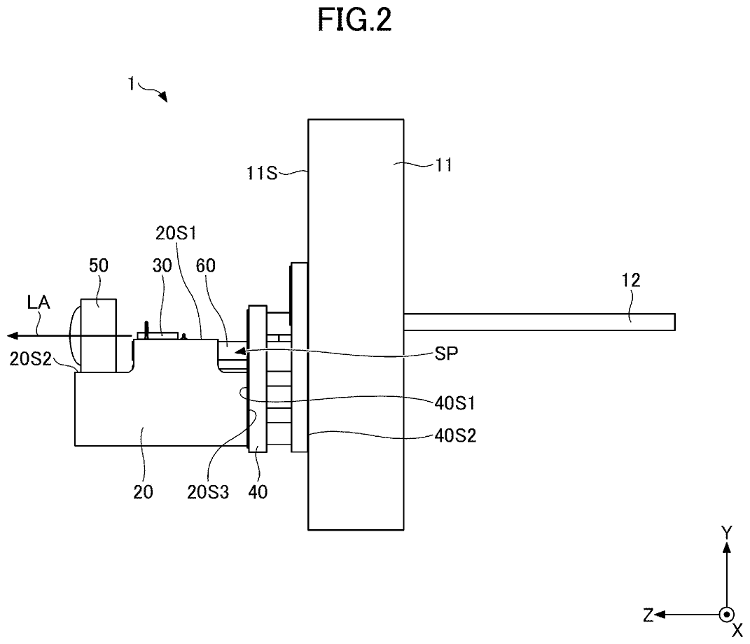

FIG. 2 is a side view of the optical transmission module according to the first embodiment;

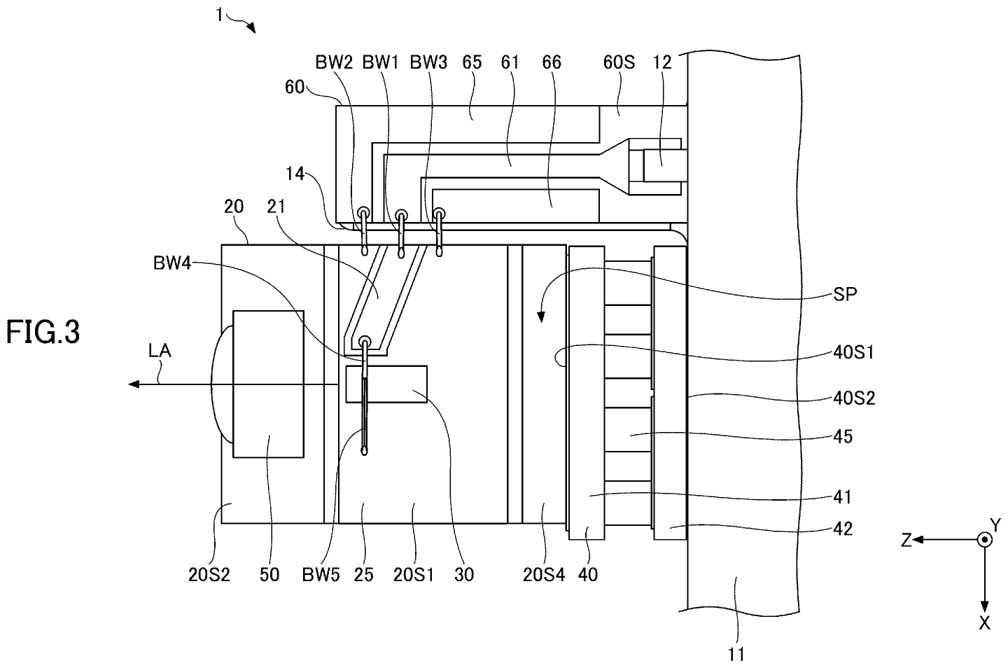

FIG. 3 is a top view of the optical transmission module according to the first embodiment;

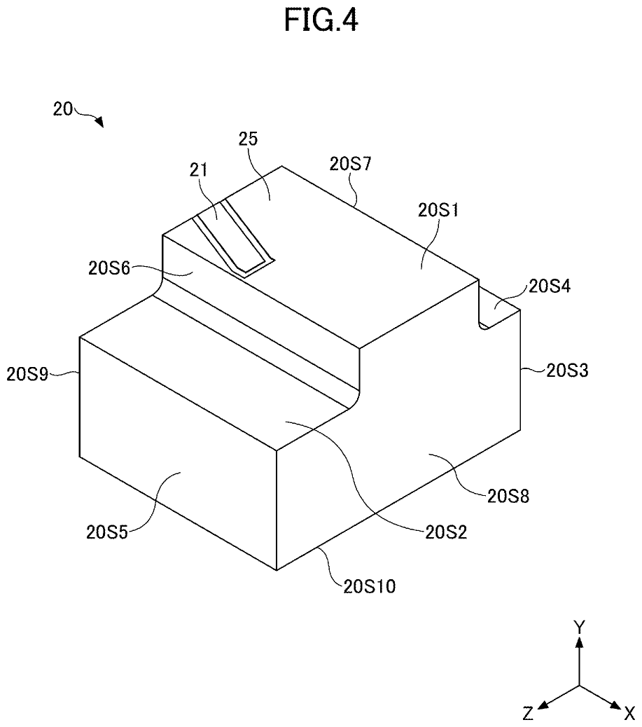

FIG. 4 is a perspective view of a dielectric block of the optical transmission module according to the first embodiment;

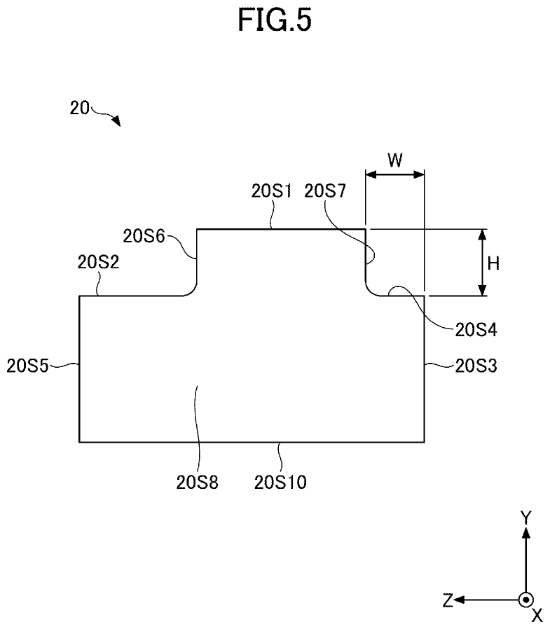

FIG. 5 is a side view of the dielectric block of the optical transmission module according to the first embodiment;

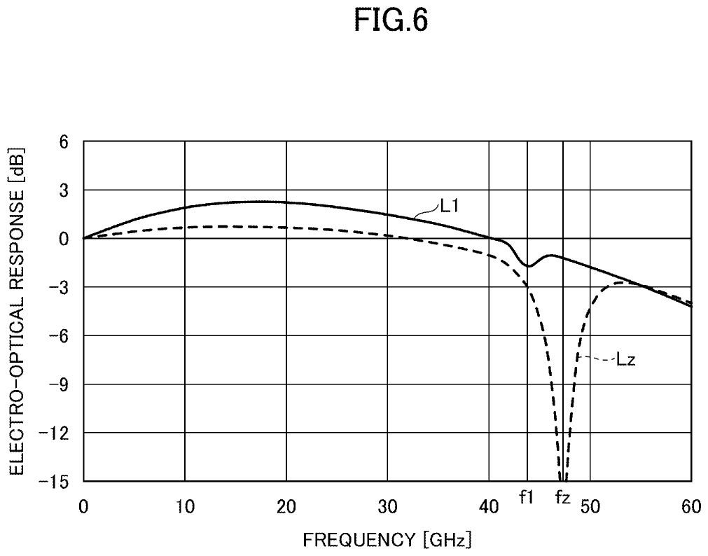

FIG. 6 illustrates frequency characteristics of the optical transmission module according to the first embodiment;

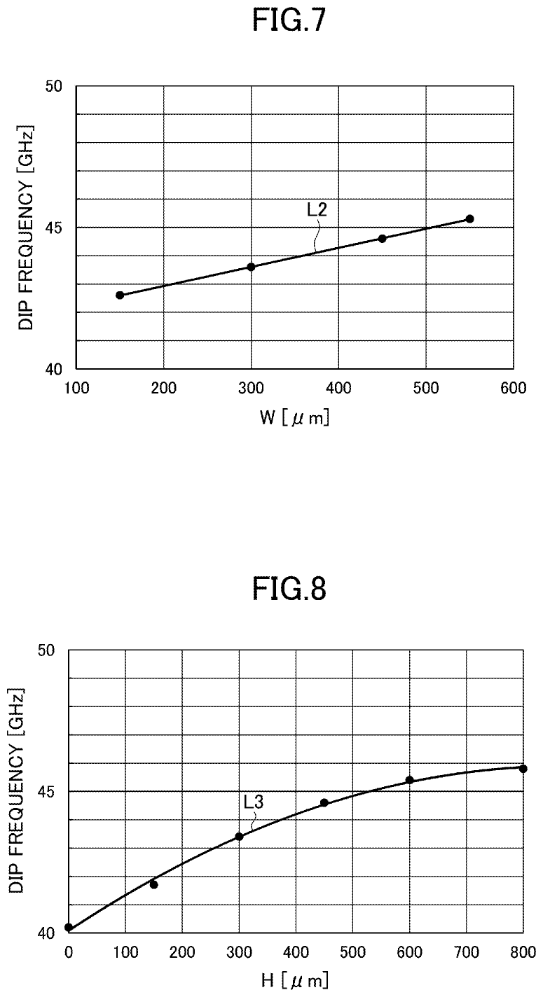

FIG. 7 is a graph illustrating an analysis result of a dip frequency of the optical transmission module according to the first embodiment;

FIG. 8 is a graph illustrating an analysis result of the dip frequency of the optical transmission module according to the first embodiment;

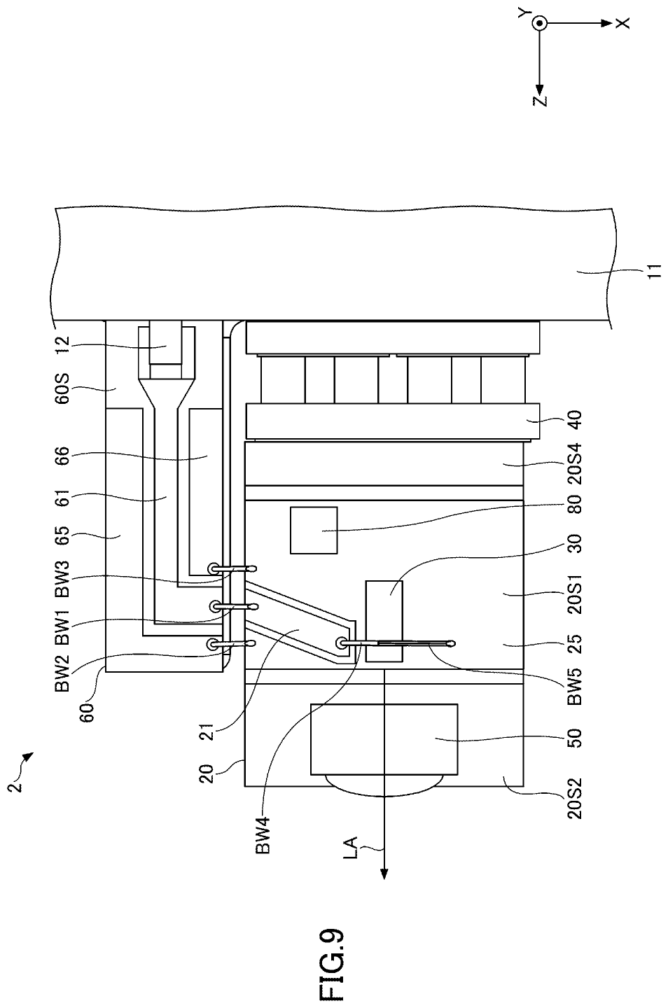

FIG. 9 is a top view of an optical transmission module according to a second embodiment; and

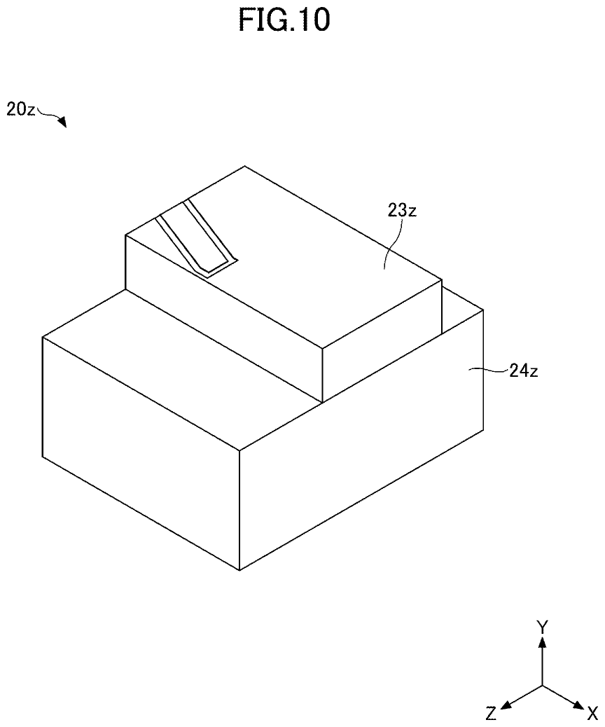

FIG. 10 is a perspective view of a dielectric block of an optical transmission module of a comparative example.

### DETAILED DESCRIPTION

### Details of Embodiments of Present Disclosure

Specific examples of an optical transmission module of the present disclosure will be described below with reference to the drawings. Note that the present invention is not limited to these examples, but is defined by the claims, and is intended to include all modifications within the meaning and range equivalent to the claims.

In the description of the specification and the drawings according to the embodiments, components having substantially the same or corresponding functions are denoted by the same reference numerals, and redundant description may be omitted. In addition, in order to facilitate understanding, the scale of each unit in the drawings may be different from the actual scale.

In directions such as parallel, right-angled, orthogonal, horizontal, vertical, up-down, left-right, and the like, deviation is allowed to an extent that does not impair the effect of the embodiment. The shape of the corner portion is not limited to a right angle, and may be rounded in an arcuate shape. Parallel, right-angled, orthogonal, horizontal, and vertical may include substantially parallel, substantially right-angled, substantially orthogonal, substantially horizontal, and substantially vertical. For example, “substantially parallel” indicates that even if two lines or two planes are not completely parallel to each other, they can be treated as parallel to each other within an allowable range in manufacturing. Other terms such as “substantially right-angled”, “substantially orthogonal”, “substantially horizontal”, and “substantially vertical” are also intended to be respectively treated as “right-angled”, “orthogonal”, “horizontal”, “vertical”, as long as the mutual positional relationship between two lines or surfaces is within a range allowable in manufacturing, similarly to “substantially parallel”.

### First Embodiment

An optical transmission module 1 according to a first embodiment will be described. FIG. 1 is a perspective view of the optical transmission module 1 according to the first embodiment. FIG. 2 is a side view of the optical transmission module 1 according to the first embodiment. FIG. 3 is a top view of the optical transmission module 1 according to the first embodiment.

In the drawings, an XYZ orthogonal coordinate system may be illustrated for convenience of explanation. For example, with respect to a coordinate axis perpendicular to the paper surface of the drawing, when a cross mark is illustrated in a circle of the coordinate axis, the depth direction with respect to the paper surface represents a positive region of the coordinate axis, and when a black circle mark is illustrated in a circle of the coordinate axis, the front side with respect to the paper surface represents a positive region of the coordinate axis. However, the coordinate system mainly indicates directions for description, and does not limit coordinates of the optical transmission module and each component of the present disclosure.

In the present disclosure, a Z-axis is the output direction of an optical signal of the optical transmission module 1 unless otherwise specified. In other words, an optical axis of the optical signal output from the optical transmission module 1 is parallel to the Z-axis. An X-axis and a Y-axis are directions perpendicular to the Z-axis. Unless otherwise specified, coordinate axes having the same names shown in the drawings represent the same ones. For example, the X-axis in FIG. 1 represents the same as the X-axis in FIG. 2. The side view in FIG. 2 corresponds to a side view observed when the optical transmission module 1 is viewed from the positive region of the X-axis toward the negative region of the X-axis. The top view in FIG. 3 corresponds to a top view observed when the optical transmission module 1 is viewed from the positive region of the Y-axis toward the negative region of the Y-axis. In the direction indicated by the Z-axis (the Z-axis direction), a direction in which the value of the Z-axis increases may be referred to as “front” or “forward”, and a direction in which the value of the Z-axis decreases may be referred to as “rear” or “rearward”. In the direction indicated by the Y-axis (Y-axis direction), a direction in which the value of the Y-axis increases may be referred to as “up” or “upward”, and a direction in which the value of the Y-axis decreases may be referred to as “down” or “downward”.

The optical transmission module 1 converts an electrical signal into an optical signal. The optical transmission module 1 outputs the optical signal along the Z-axis direction. The optical transmission module 1 includes a metal base 10, a dielectric block 20, an optical semiconductor element 30, a temperature regulating element 40, a lens 50, and a board 60. The optical transmission module 1 may further include a cylindrical housing (not shown), and the optical semiconductor element 30 may be hermetically sealed by the housing and the metal base 10. The optical transmission module is, for example, a coaxial transmitter optical sub-assembly (TOSA).

The metal base 10 includes a substantially disk-shaped body 11, a signal terminal 12, and an insulator 13. The body 11 has a through hole 11h. The signal terminal 12 extends in the Z-axis direction (a first direction). The signal terminal 12 is provided so as to penetrate the through hole 11h along the Z-axis direction. The signal terminal 12 has, for example, a columnar outer shape having a central axis parallel to the Z-axis. The signal terminal 12 is fixed to the body 11 by the insulator 13 filled in the through hole 11h. The signal terminal 12 is insulated from the body 11 by the insulator 13. The insulator 13 is, for example, a sealing glass material. The signal terminal 12 is a terminal for receiving the electrical signal from the outside.

The body 11 is made of metal. Since the body 11 is famed of a metal, heat generated in the temperature regulating element 40 connected to the body 11 is conducted to the outside. The metal forming the body 11 preferably has a high thermal conductivity.

The metal base 10 has a flat inner surface 11S on the front side. For example, the inner surface 11S intersects a direction in which the signal terminal 12 extends. The signal terminal 12 has one end (a first end) protruding forward along the Z-axis direction from the inner surface 11S. In addition, the signal terminal 12 has the other end (a second end) protruding rearward along the Z-axis direction from a surface (an outer surface) opposite to the inner surface 11S. In the signal terminal 12, the electrical signal input to the second end propagates to the first end. The inner surface 11S is, for example, hermetically sealed by the housing. The metal base 10 has airtightness between the inner surface 11S and the outer surface. A support portion 14 is provided to extend forward from the inner surface 11S of the metal base 10. Another member may be mounted on the metal base 10 as the support portion 14. For example, the support portion 14 may be a block that is configured independently from the metal base 10 and has an outer shape of a quadrangular prism extending along the Z-axis direction, and the rear end surface of the block may be bonded to the inner surface 11S. The block of the support portion 14 is formed of, for example, metal. In this case, the metal base 10 and the support portion 14 can be electrically connected to each other by bonding with an electrical conductive adhesive. For example, by setting the potential of the body 11 to the ground potential, the potential of the support portion 14 is set to the ground potential. By forming the support portion 14 as a member separate from the metal base 10, the position of the support portion 14 bonded to the inner surface 11S can be easily changed. The block of the support portion 14 may be formed of an insulating material. In this case, the support portion 14 is electrically floating. The board 60 is mounted on the support portion 14 along the Y-axis direction and fixed to the support portion 14.

In FIG. 1, the optical transmission module 1 includes one signal terminal 12, but may include a plurality of terminals similar to the signal terminal 12 depending on the function of the optical transmission module 1. For example, a terminal for supplying power to the optical semiconductor element 30 and the temperature regulating element 40, a terminal for providing a reference potential (for example, a ground potential), a terminal for transmitting an electrical signal for control, and the like may be provided.

The dielectric block 20 holds the optical semiconductor element 30 and the lens 50. The dielectric block 20 is formed of, for example, a dielectric substance such as ceramic. The ceramic is, for example, aluminum nitride. Forming the dielectric block 20 as a monolithic member by using ceramic enables to suppress deterioration of a frequency characteristic of an electrical signal propagating through a signal line 21 on a semiconductor plane 20S1. The monolithic member indicates a single part that has no subparts and cannot be disassembled into subparts. For example, the monolithic member is made of a ceramic block and shaped by cutting work. The semiconductor plane 20S1 will be described later.

The shape of the dielectric block 20 will be described. FIG. 4 is a perspective view of the dielectric block 20 of the optical transmission module 1 according to the first embodiment. FIG. 5 is a side view of the dielectric block 20 of the optical transmission module 1 according to the first embodiment. FIG. 5 corresponds to a side view observed when the dielectric block 20 is viewed from the positive region of the X-axis toward the negative region of the X-axis.

The dielectric block 20 has a substantially rectangular parallelepiped shape in which a part near a central portion of an upper surface perpendicular to the Y-axis direction protrudes upward along the Y-axis direction on the upper surface. The dielectric block 20 has the semiconductor plane 20S1, an optical plane 20S2, and an upper surface 20S4, which are parallel to each other. Each of the semiconductor plane 20S1, the optical plane 20S2, and the upper surface 20S4 is a plane extending along the direction indicated by the X-axis (the X-axis direction) and the Z-axis direction. Each of the semiconductor plane 20S1, the optical plane 20S2, and the upper surface 20S4 is a plane perpendicular to the Y-axis direction. In the Y-axis direction, the position of the semiconductor plane 20S1 is formed such that the coordinate value of the semiconductor plane 20S1 is larger than the coordinate value of the optical plane 20S2 and the coordinate value of the upper surface 20S4, with respect to the position of the optical plane 20S2 and the position of the upper surface 20S4. When the semiconductor plane 20S1 is viewed along the Y-axis direction (that is, in a plan view of the semiconductor plane 20S1), the semiconductor plane 20S1 is disposed between the optical plane 20S2 and the upper surface 20S4 (see FIG. 3). Therefore, the dielectric block 20 has a shape in which the semiconductor plane 20S1 protrudes upward with respect to the optical plane 20S2 and the upper surface 20S4. The dielectric block 20 has a vertical surface 20S6 that connects the semiconductor plane 20S1 to the optical plane 20S2. The dielectric block 20 has a vertical surface 20S7 connecting the semiconductor plane 20S1 to the upper surface 20S4. Each of the vertical surfaces 20S6 and 20S7 is a plane extending along the X-axis direction and the Y-axis direction. The vertical surfaces 20S6 and 20S7 are planes perpendicular to the semiconductor plane 20S1, the optical plane 20S2, and the upper surface 20S4. Note that a bonding portion between the vertical surface 20S6 and the optical plane 20S2 and a bonding portion between the vertical surface 20S7 and the upper surface 20S4 may form fillets (concave curved surfaces).

The dielectric block 20 has a thermal plane 20S3 on the rear side. The thermal plane 20S3 is a plane extending along the X-axis direction and the Y-axis direction. The thermal plane 20S3 crosses the Z-axis direction. For example, the Z-axis direction is perpendicular to the thermal plane 20S3. In addition, the dielectric block 20 has a front surface 20S5 on the front side, a side surface 20S8 and a side surface 20S9 in the X-axis direction, and a bottom surface 20S10 on the lower side. The front surface 20S5 is a plane extending along the X-axis direction and the Y-axis direction. The side surfaces 20S8 and 20S9 are planes extending along the Y-direction and the Z-axis direction. The side surface 20S9 is located opposite to the side surface 20S8. The bottom surface 20S10 is a plane extending along the X-axis direction and the Z-axis direction.

A distance between the rear end of the semiconductor plane 20S1 and the thermal plane 20S3 is set to be a width W in the Z-axis direction. In other words, when viewed from the Y-axis direction (in a plan view of the semiconductor plane 20S1), a distance between the semiconductor plane 20S1 and a temperature control surface 40S1 of the temperature regulating element 40 is set to the width W. The temperature control surface 40S1 will be described later. The width W is a distance in the Z-axis direction between the semiconductor plane 20S1 and the thermal plane 20S3.

In the Y-axis direction, the semiconductor plane 20S1 and the upper end of the thermal plane 20S3 are separated from each other by a depth H. The depth H is a distance in the Y-axis direction between the semiconductor plane 20S1 and the thermal plane 20S3. When the semiconductor plane 20S1 and the upper surface 20S4 are parallel to each other, the depth H corresponds to a distance between the semiconductor plane 20S1 and the upper surface 20S4. When the dielectric block 20 is connected to the temperature regulating element 40, a vacant space SP is formed between the semiconductor plane 20S1 and the upper surface 20S4 in the Y-axis direction and between the vertical surface 20S7 and the thermal plane 20S3 in the Z-axis direction. The vacant space SP is defined by planes each including the semiconductor plane 20S1, the upper surface 20S4, the vertical surface 20S7, and the thermal plane 20S3 with respect to the Y-axis direction and the Z-axis direction. The vacant space SP is defined by a plane including the side surface 20S8 and a plane including the side surface 20S9 with respect to the X-axis direction. The vacant space SP is an empty space in which there is no material constituting the dielectric block 20.

The optical semiconductor element 30 is mounted on the semiconductor plane 20S1. Further, a capacitor, a resistor, or the like may be mounted on the semiconductor plane 20S1. Conductive patterns are formed on the semiconductor plane 20S1. For example, the signal line 21 and a ground line (also referred to as a ground pattern when it spreads widely) 25 are formed in the semiconductor plane 20S1. The signal line 21 and the ground line 25 are examples of conductive patterns, and are famed of a conductive material (for example, metal). The signal line 21 surrounded by the ground line 25 is, for example, a transmission line that transmits an electrical signal to the optical semiconductor element 30. By constituting the signal line 21 as a transmission line, the transmission characteristics of the electrical signal to the optical semiconductor element 30 can be improved. The optical semiconductor element 30 outputs an optical signal in response to the input electrical signal. The optical signal output from the optical transmission module 1 is generated by the optical semiconductor element 30. For example, the optical signal modulated by the electrical signal is output from the optical semiconductor element 30. Therefore, for example, the transmission line improves the transmission characteristics of the electrical signal, so that the frequency characteristic of the intensity of the optical signal with respect to the intensity of the electrical signal has a wide band up to a higher frequency. The optical semiconductor element 30 is installed on the ground line 25.

In addition to the optical semiconductor element 30, for example, at least one of a termination resistor, a termination capacitor, a bypass capacitor, and a terminal may be mounted on the semiconductor plane 20S1. Further, a plurality of conductive patterns other than the signal line 21 and the ground line 25 may be formed on the semiconductor plane 20S1. The plurality of conductive patterns, the termination resistor, the termination capacitor, the bypass capacitor, and the like may constitute a peripheral circuit for causing the optical semiconductor element 30 to perform a predetermined operation. For example, the termination resistor is used as a termination resistor for terminating the transmission line to a predetermined voltage.

The lens 50 is mounted on the optical plane 20S2. The optical plane 20S2 is provided below the semiconductor plane 20S1 in consideration of the size of the lens 50 so that an optical axis of the lens 50 coincides with an optical axis LA of the optical signal output from the optical semiconductor element 30 when the lens 50 is mounted. For example, when the lens 50 is mounted on the optical plane 20S2, the distance between the semiconductor plane 20S1 and the optical plane 20S2 is set according to the focal distance of the lens 50 so that the optical signal output from the optical semiconductor element 30 mounted on the semiconductor plane 20S1 is appropriately incident on the lens 50. For example, the optical plane 20S2 is formed to be parallel to the semiconductor plane 20S1. Thus, the optical signal output forward from the optical semiconductor element 30 can be incident perpendicularly to the input face of the lens 50 provided perpendicularly to the optical plane 20S2. For example, in the Y-axis direction, the distance between the optical plane 20S2 and the semiconductor plane 20S1 may be determined according to a distance from the semiconductor plane 20S1 to an emission point of the optical signal of the optical semiconductor element 30 and a distance from the optical plane 20S2 to a central axis (the optical axis) of the lens 50. The lens 50 is fixed to the optical plane 20S2 by using, for example, a curable resin. The lens 50 is, for example, a collimating lens that converts the light conically emitted from the optical semiconductor element 30 into collimated light.

Both the semiconductor plane 20S1 on which the optical semiconductor element 30 is mounted and the optical plane 20S2 on which the lens 50 is mounted face upward. In other words, the semiconductor plane 20S1 and the optical plane 20S2 are planes perpendicular to the Y-axis direction, that is, parallel to the Z-axis direction. Because the semiconductor plane 20S1 and the optical plane 20S2 are oriented in the same direction, components such as the optical semiconductor element 30 and the lens 50 can be mounted from the same direction. The optical semiconductor element 30 is mounted on the semiconductor plane 20S1 so as to output the optical signal forward. That is, the optical semiconductor element 30 is mounted on the semiconductor plane 20S1 so that the optical axis LA of the optical signal to be output is along the Z-axis direction.

The thermal plane 20S3 is connected to the temperature control surface 40S1 of the temperature regulating element 40. The dielectric block 20 is cooled or heated by the temperature regulating element 40 by connecting the thermal plane 20S3 to the temperature control surface 40S1 of the temperature regulating element 40. The thermal plane 20S3 and the temperature regulating element 40 are in contact with each other. For example, the thermal plane 20S3 and the temperature control surface 40S1 has a surface contact with each other.

The optical semiconductor element 30 generates an optical signal modulated by an input electrical signal. The optical semiconductor element 30 emits the optical signal along the optical axis LA. The optical semiconductor element 30 includes, for example, a laser diode or an electro-absorption light modulator. When the optical semiconductor element 30 is the electro-absorption light modulator, a laser diode for generating continuous light to be modulated may be provided on the same semiconductor chip. For example, the optical semiconductor element 30 may be a light modulator integrated semiconductor laser in which an electro-absorption light modulator is integrated. The optical axis LA is provided at a predetermined distance from the semiconductor plane 20S1 along the Y-axis direction according to the structure of the optical semiconductor element 30. The optical semiconductor element 30 generates Joule heat by consuming electric power when generating the optical signal.

The optical semiconductor element 30 is connected to the signal line 21 by a bonding wire BW4. Further, the optical semiconductor element 30 is connected to a termination resistor (not shown) by a bonding wire BW5, for example, and is connected to the ground line 25 via the termination resistor. Note that a termination capacitor may be connected to the termination resistor in series.

The temperature regulating element 40 cools or heats the dielectric block 20. The temperature regulating element 40 is, for example, a thermoelectric cooler (TEC). The temperature regulating element 40 includes a plurality of Peltier elements 45 that are Peltier-bonded. The temperature regulating element 40 cools or heats a component attached to the temperature control surface 40S1 by being supplied with electric power from a terminal (not shown) provided on the metal base 10. For example, in order to maintain the peak wavelength of the optical signal at a predetermined value, it is necessary to maintain the temperature of the optical semiconductor element 30 at a predetermined laser temperature. For example, when the temperature outside the optical transmission module 1 is higher than the predetermined laser temperature, the temperature regulating element 40 cools the temperature control surface 40S1 to keep the temperature of the optical semiconductor element 30 at the predetermined laser temperature. When the temperature outside the optical transmission module 1 is lower than the predetermined laser temperature, the temperature regulating element 40 heats the temperature control surface 40S1 to keep the temperature of the optical semiconductor element 30 at the predetermined laser temperature. Heat generated in the semiconductor plane 20S1 is conducted to the temperature control surface 40S1 through the dielectric block 20. Therefore, in order to efficiently adjust the laser temperature of the optical semiconductor element 30 to a predetermined temperature by the temperature regulating element 40, it is preferable that the thermal conductivity of the dielectric block has a large value.

The temperature regulating element 40 is provided between the metal base 10 and the thermal plane 20S3 of the dielectric block 20 in the Z-axis direction. In detail, the temperature regulating element 40 is provided between the inner surface 11S of the front side of the body 11 of the metal base 10 and the thermal plane 20S3 of the rear side of the dielectric block 20. The temperature control surface 40S1 of the temperature regulating element 40 is connected to the thermal plane 20S3 of the dielectric block 20. For example, the thermal plane 20S3 is fixed to the temperature control surface 40S1 by an adhesive. The heat dissipation surface 40S2 opposite to the temperature control surface 40S1 of the temperature regulating element 40 is connected to the inner surface 11S of the metal base 10. For example, the heat dissipation surface 40S2 may be fixed to the inner surface 11S by an adhesive. By the action of the temperature regulating element 40, the heat dissipation surface 40S2 dissipates heat when the temperature control surface 40S1 absorbs heat (cools), and the heat dissipation surface 40S2 absorbs heat when the temperature control surface 40S1 dissipates heat (heats). The temperature control surface 40S1 and the heat dissipation surface 40S2 are parallel to each other. Accordingly, as will be described later, the lens 50 is mounted on the optical plane 20S2 so that the central axes of the lens 50 and the optical plane 20S2 are parallel to each other, whereby the optical axis LA of the optical signal can be provided perpendicular to the inner surface 11S of the metal base 10. Heat radiated from the heat dissipation surface 40S2 is conducted through the body 11 and diffused to the surroundings.

The temperature regulating element 40 includes a board 41, a board 42, and the plurality of Peltier elements 45. For example, the boards 41 and 42 are made of ceramic. The plurality of Peltier elements 45 are provided between the board 41 and the board 42. The board 41 has the temperature control surface 40S1 at the front. Further, the board 42 has the heat dissipation surface 40S2 on the rear side. Heat absorbed by the board 41 is radiated by the board 42 by passing a current through the plurality of Peltier elements 45 in a predetermined direction, and the dielectric block 20 connected to the temperature control surface 40S1 is cooled. Alternatively, the dielectric block 20 connected to the temperature control surface 40S1 may be heated by passing a current through the plurality of Peltier elements 45 in a direction opposite to the predetermined direction to dissipate heat absorbed by the board 42 through the board 41. In this way, the temperature control surface 40S1 of the temperature regulating element 40 is heated and cooled, whereby the temperature of the optical semiconductor element 30 mounted on the semiconductor plane 20S1 via the dielectric block 20 is regulated.

The lens 50 is an optical lens that collects the optical signal emitted from the optical semiconductor element 30. The lens 50 is formed of, for example, optical glass. The lens 50 has, for example, an input face facing the optical semiconductor element 30 in the Z-axis direction, and an output face opposite to the input face. For example, the lens 50 receives the optical signal emitted from the optical semiconductor element 30 at the input face and outputs the optical signal as collimated light from the output face.

The lens 50 is mounted on the optical plane 20S2 of the dielectric block 20. The lens 50 is fixed to the optical plane 20S2 by, for example, an adhesive. The adhesive is, for example, an ultraviolet curable resin. When the lens 50 is fixed to the optical plane 20S2, the position of the lens 50 is adjusted (aligned) in the X-axis direction and the Y-axis direction so that the optical axis of the lens 50 coincides with the optical axis LA of the optical signal output from the optical semiconductor element 30, and then the lens 50 is fixed. For example, in the XY plane, it is preferable that the position of the optical axis LA coincides with the position of the optical axis of the lens 50. Also in the Z-axis direction, for example, alignment may be performed so that light output from the output face becomes collimated light. The lens 50 has a bottom surface facing the optical plane 20S2. For example, an adhesive before being hardened is applied between the bottom surface of the lens 50 and the optical plane 20S2, and the lens 50 is fixed to the optical plane 20S2 by heating the adhesive after alignment and irradiating the adhesive with ultraviolet rays to harden the adhesive. For example, the input face and the output face of the lens 50 are perpendicular to the bottom surface of the lens 50. The lens 50 is fixed to the optical plane 20S2 such that the optical axis of the lens 50 is parallel to the optical plane 20S2. Because the optical signal output from the optical semiconductor element 30 spreads in the X-axis direction and the Y-axis direction as it travels forward, the position of the lens 50 in the Z-axis direction with respect to the optical plane 20S2 may be determined by adjusting (aligning) the position of the lens 50 in the Z-axis direction while monitoring the intensity of the light output from the lens 50 with a photodetector so that the collimated light is output from the lens 50.

The board 60 transmits an electrical signal input to the signal terminal 12 to the optical semiconductor element 30. The board 60 extends along the Z-axis direction. The board 60 is fixed to, for example, an upper surface of the support portion 14. The board 60 includes a signal line 61, a ground line 65, and a ground line 66 on an upper surface 60S facing upward. The signal line 61, the ground line 65, and the ground line 66 are formed of, for example, metal. The signal line 61 is electrically connected to the signal terminal 12. The ground line 65 and the ground line 66 are grounded. The signal line 61 transmits an electrical signal from the signal terminal 12 to the signal line 21 provided in the semiconductor plane 20S1. The electrical signal converted into the optical signal by the optical semiconductor element 30 includes, for example, high-frequency components equal to or higher than 30 GHz. In order not to deteriorate the waveform quality of the electrical signal, the signal line 61 is formed to constitute a transmission line together with the ground line 65 and the ground line 66. For example, the signal line 61 is formed such that a predetermined interval is secured between the signal line 61 and each of the ground line 65 and the ground line 66.

One end of the signal line 61 is connected to, for example, the signal line 21 in the semiconductor plane 20S1 by a bonding wire BW1. The ground line 65 is connected to the ground line 25 of the semiconductor plane 20S1 by a bonding wire BW2. The ground line 66 is connected to the ground line 25 of the semiconductor plane 20S1 by a bonding wire BW3. The bonding wires BW1, BW2, and BW3 are formed so as to extend along the X-axis direction when viewed from the Y-axis direction. For example, the position of one end of each of the bonding wires BW1, BW2, and BW3 on the upper surface 60S in the X-axis direction is the same for all of the bonding wires. The position of the other end of each of the bonding wires BW1, BW2, and BW3 on the semiconductor plane 20S1 in the X-axis direction is the same for all of the bonding wires. The lengths of the bonding wires BW1, BW2, and BW3 are preferably set to be short in order to reduce the inductance. Lengths of the bonding wires BW1, BW2, and BW3 may be set to be equal to each other. Further, the diameters of the bonding wires BW1, BW2, and BW3 may be set to be equal to each other. It is preferable that the position of the upper surface 60S of the board 60 in the Y-axis direction is close to the position of the semiconductor plane 20S1 of the dielectric block 20 in the Y-axis direction. By bringing the position (height) of the upper surface 60S in the Y-axis direction and the position (height) of the semiconductor plane 20S1 in the Y-axis direction close to each other, the lengths of the bonding wires BW1, BW2, and BW3 can be shortened. For example, the difference between the height of the upper surface 60S and the height of the semiconductor plane 20S1 is preferably 100 micrometers (μm) or less.

The other end of the signal line 61 is connected to the signal terminal 12. More specifically, the other end of the signal line 61 is connected to one end of the signal terminal 12 protruding from the inner surface 11S. The connection between the other end of the signal line 61 and the one end of the signal terminal 12 may be performed by an electrical conductive adhesive or solder, or may be performed by bonding wire. It is preferable that the other end of the signal line 61 and the one end of the signal terminal 12 are close to each other in terms of signal transmission. For example, the position of the support portion 14 on the inner surface 11S may be determined such that the other end of the signal line 61 and the one end of the signal terminal 12 are close to each other. The shape and size of the board 60 may be set such that one end of the signal line 61 is close to the semiconductor plane 20S1 and the other end of the signal line 61 is close to the signal terminal 12. A lower surface opposite to the upper surface of the board 60 is connected to the support portion 14. For example, the board 60 may be bonded to the upper surface of the support portion 14 by an electrical conductive adhesive or solder. The lower surface of the board 60 may be metallized with metal to form a conductive thin film. When the support portion 14 is set to the ground potential, the thin film formed on the lower surface of the board 60 is set to the ground potential.

The frequency characteristics of the electro-optical response of the optical transmission module 1 are indicated in FIG. 6. The vertical axis of the graph in FIG. 6 is the electro-optical response (unit:decibels (dB)). The horizontal axis of the graph in FIG. 6 is a signal frequency (unit:gigahertz (GHz)). The electrical-optical response represents the magnitude (spectrum) of the signal intensity of the optical signal output from the optical semiconductor element 30 with respect to the signal intensity of the electrical signal input to the signal terminal 12. The values on the vertical axis represent, for example, values based on the values of the signal intensities of the optical signals at frequencies equal to or lower than 1 GHz. The value of the electro-optical response indicated in FIG. 6 is preferably close to zero because as the value of the electro-optical response decreases in the negative range, the degradation of the optical signal increases. FIG. 6 indicates the frequency characteristic (a solid line L1) of the optical transmission module 1 and the frequency characteristic (a broken line Lz) of an optical transmission module including the dielectric block 20z illustrated in FIG. 10 instead of the dielectric block 20 as a comparative example. The frequency characteristics indicated in FIG. 6 indicates the results of analyzing the electro-optical response of the optical transmission modules using electromagnetic field analysis.

The optical transmission module of the comparative example includes the dielectric block 20z in which a dielectric block 23z and a dielectric block 24z are connected, instead of the dielectric block 20 of the optical transmission module 1. The dielectric block 23z is a carrier having an upper surface on which an optical semiconductor element is mounted. The dielectric block 24z is a sub-mount for supporting the dielectric block 23z. A bottom surface of the dielectric block 23z facing downward is connected to an upper surface of the dielectric block 24z facing upward. In order to connect the dielectric block 23z to the dielectric block 24z, for example, a conductive thin film is provided on a connection portion between the dielectric block 23z and the dielectric block 24z (i.e., between the bottom surface of the dielectric block 23z and the upper surface of the dielectric block 24z). The conductive thin film is formed of, for example, metal. The conductive thin film is electrically floating. The outer shape of the dielectric block 20z is the same as that of the dielectric block 20 except for details. For example, the lengths in the Z-axis direction, the Y-axis direction, and the X-axis direction of the dielectric block 20z are the same as the respective lengths of the dielectric block 20. The area of the upper surface of the dielectric block 23z is the same as the area of the semiconductor plane 20S1 of the dielectric block 20.

In FIG. 6, the solid line L1 is an example of the frequency characteristic of the electro-optical response of the optical transmission module 1 according to the first embodiment. The broken line Lz is an example of the frequency characteristic of the electro-optical response of the optical transmission module of the comparative example. From the comparison between the solid line L1 and the broken line Lz, the optical transmission module 1 has less fluctuation in the electro-optical response up to higher frequencies (for example, 50 GHz) than the optical transmission module of the comparative example, and has a flat characteristic. In particular, in the optical transmission module of the comparative example, the electro-optical response drops significantly at frequencies ranging from 45 to around 50 GHz. In the frequency characteristic, a drop (deterioration) of the electro-optical response at such a specific frequency may be referred to as a dip, and a frequency at which the dip occurs may be referred to as a dip frequency. The optical transmission module 1 has a characteristic excellent in flatness without a large drop in the electro-optical response in a range from a frequency of 1 GHz or less to a frequency of 60 GHz. For example, the range of frequencies until the electro-optical response becomes −3 dB is referred to as the 3-dB bandwidth, and the 3-dB bandwidth of the solid line L1 is 55 GHz. The inventors have found that the optical transmission module using the dielectric block 20z of the comparative example does not cause a dip at signal frequencies lower than 30 GHz, but causes a dip at signal frequencies higher than 30 GHz. For example, in the comparative example, a large dip occurs at the dip frequency fz=47 GHz. The 3-dB bandwidth of the broken line Lz is limited to 43 GHz due to the influence of the dip. For example, in the IEEE 800GbE or more optical interface (P802.3df project), signals are transmitted at a 100 Gbps data signaling rate in each lane of 8 lanes. At this time, for example, the symbol rate is 50G baud, and the electrical signal (a modulation signal) for driving the optical semiconductor element 30 includes a frequency equal to or higher than 30 GHz. Therefore, the 3-dB bandwidth is preferably equal to or higher than 50 GHz. The inventors further found that dip is significantly improved by using the dielectric block 20 instead of the dielectric block 20z. That is, it has been found that the conductive thin film on the dielectric block 20z affects the signal transfer of the electrical signal from the signal terminal 12 to the optical semiconductor element 30 when the frequency of the electrical signal becomes high. However, although the influence on signal transmission is reduced by removing the above-described conductive thin film, it has also been found that dip still occurs. For example, in the solid line L1 in FIG. 6, a dip occurs at dip frequency f1=43 GHz, although the magnitude of the dip is as small as 3 dB or less.

The dip found in the optical transmission module 1 of the embodiment of the present disclosure will now be described. Characteristics observed when the width W and the depth H in FIG. 5 are modified in the optical transmission module 1 will be described. The width W and the depth H are parameters related to the shape of the vacant space SP famed by the dielectric block 20 and the temperature regulating element 40. Electromagnetic field analysis was performed on the relationship between the dip frequency near the frequency of 40 GHz of the electro-optical response and the shape of the vacant space SP.

FIG. 7 is a graph indicating the dip frequency observed when the width W of the optical transmission module 1 according to the first embodiment is changed. The value of the depth H set in the electromagnetic field analysis indicated in FIG. 7 is 450 micrometers. The vertical axis of the graph in FIG. 7 is the dip frequency (unit: gigahertz (GHz)). The horizontal axis of the graph in FIG. 7 is width W (unit: micrometer (μm)).

FIG. 8 is a graph indicating the dip frequency observed when the depth H of the optical transmission module 1 according to the first embodiment is changed. The value of the width W set in the electromagnetic field analysis of FIG. 8 is 450 micrometers. The vertical axis of the graph in FIG. 8 is the dip frequency (unit: gigahertz (GHz)). The horizontal axis of the graph in FIG. 8 is depth H (unit: micrometer (μm)).

As indicated in FIG. 7 and FIG. 8, the value of the dip frequency increases as each of the width W and the depth H increases. The inventors have found that the relatively small dip as indicated by the solid line L1 in FIG. 6 is due to stray capacitance between the semiconductor plane 20S1 and the temperature control surface 40S1 of the temperature regulating element 40. Therefore, it has also been found that the stray capacitance between the semiconductor plane 20S1 and the temperature control surface 40S1 of the temperature regulating element 40 can be reduced by increasing each of the width W and the depth H. For example, when each of the width W and the depth H increases, the volume of the vacant space SP increases. The vacant space SP is filled with a gas. For example, when the vacant space SP is filled with air, the relative dielectric constant is approximately 1. For example, when the optical semiconductor element 30 is hermetically sealed, the vacant space SP is filled with a sealing gas. When the vacant space SP is filled with the dielectric substance forming the dielectric block 20, the relative dielectric constant becomes larger than 1. For example, the relative dielectric constant of aluminum nitride is 8 or more at the frequency of 1 MHz. Therefore, by providing the vacant space SP, for example, it can be expected that the stray capacitance described above is significantly reduced to the degree of the ratio between the relative dielectric constant of aluminum nitride and the relative dielectric constant of gas. As described above, the inventors have found that when the signal frequency is higher than 30 GHz, the dip frequency can be increased by reducing the stray capacitance between the semiconductor plane 20S1 and the temperature control surface 40S1 of the temperature regulating element 40, thereby improving the frequency characteristic of the optical signal. For example, the waveform quality of the optical signal transmitted from the optical transmission module 1 can be improved by reducing the degradation due to the dip of the frequency characteristic of the optical signal. The width W is preferably 300 micrometers or more. In particular, the width W is more preferably 450 micrometers or more. Further, the depth H is preferably 300 micrometers or more. In particular, the depth H is more preferably 450 micrometers or more.

In the optical transmission module 1 according to the first embodiment, the optical semiconductor element 30 is mounted on the semiconductor plane 20S1 of the dielectric block 20, so that deterioration of the frequency characteristic of the electro-optical response can be reduced.

Further, because the optical transmission module 1 according to the first embodiment uses the dielectric block 20 formed as a single member, the number of components and the number of mounting processes can be reduced. In addition, because the optical transmission module 1 according to the first embodiment uses the dielectric block 20 formed as a single member, the manufacturing cost of the optical transmission module 1 can be reduced.

Furthermore, by providing the vacant space SP between the semiconductor plane 20S1 and the temperature control surface 40S1 of the temperature regulating element 40, the stray capacitance between the semiconductor plane 20S1 and the temperature control surface 40S1 can be reduced, and deterioration of the frequency characteristic of the electrical-optical response can be reduced.

### Second Embodiment

A temperature sensing element 80 for measuring the temperature at the semiconductor plane 20S1 to control the temperature regulating element 40 may be mounted on the semiconductor plane 20S1.

FIG. 9 is a top view of an optical transmission module 2 according to a second embodiment.

The optical transmission module 2 further includes the temperature sensing element 80 in addition to the optical transmission module 1. The temperature sensing element 80 is mounted on the semiconductor plane 20S1 of the dielectric block 20. The temperature sensing element 80 is, for example, a thermistor, a thermocouple, or a resistance thermometer. Note that the type of the temperature sensing element 80 is not limited as long as the element can be used for temperature measurement. The temperature regulating element 40 is controlled using the temperature measured using the temperature sensing element 80 such that the temperature of the optical semiconductor element 30 is at the desired temperature. For example, the temperature sensing element 80 is connected to an external control circuit of the temperature regulating element 40 via a terminal that is provided on the metal base 10 and transmits an electrical signal for control.

The optical transmission module 2 according to the second embodiment can control the temperature of the optical semiconductor element 30 with higher accuracy than the optical transmission module 1 according to the first embodiment. More specifically, because the optical transmission module 2 according to the second embodiment includes the temperature sensing element 80 on the semiconductor plane 20S1, the temperature sensing element 80 can be disposed close to the optical semiconductor element 30. By mounting the temperature sensing element 80 on the semiconductor plane 20S1, the temperature of the optical semiconductor element 30 can be measured more accurately. For example, a temperature difference may be generated between the semiconductor plane 20S1 and the temperature control surface 40S1 due to heat resistance of the dielectric block 20. For example, when the temperature sensing element 80 is mounted on the temperature control surface 40S1, the temperature difference is included in the difference between the temperature measured using the temperature sensing element 80 and the temperature of the optical semiconductor element 30. In the optical transmission module 2, the difference due to such a temperature difference can be eliminated. Therefore, by accurately measuring the temperature of the optical semiconductor element 30, the optical transmission module 2 can more accurately control the temperature of the optical semiconductor element 30 by the temperature regulating element 40. Further, the temperature sensing element 80 improves followability of temperature measurement with respect to a change in temperature of the optical semiconductor element 30. Therefore, the optical transmission module 2 can control the temperature of the optical semiconductor element 30 with better responsiveness to temperature change. In the semiconductor plane 20S1, the temperature sensing element 80 may be mounted away from the optical semiconductor element 30 so as not to affect signal transmission of the electrical signal. For example, in a plan view of the semiconductor plane 20S1, the distance between the temperature sensing element 80 and the vacant space SP may be set to be smaller than the distance between the temperature sensing element 80 and the signal line 21.

What is claimed is:

1. An optical transmission module comprising:
a metal base including a signal terminal which extends along a first direction;
a dielectric block including a dielectric substance, the dielectric block having a semiconductor plane, an optical plane, and a thermal plane, the semiconductor plane and the optical plane being parallel to the first direction, the thermal plane crossing the first direction, and the semiconductor plane being provided between the optical plane and the thermal plane in the first direction;
an optical semiconductor element mounted on the semiconductor plane, the optical semiconductor element being electrically connected to the signal terminal;
a temperature regulating element provided between the dielectric block and the metal base in the first direction, the temperature regulating element being connected to the thermal plane; and
a lens mounted on the optical plane.

2. The optical transmission module according to claim 1, wherein the dielectric block has a vacant space between the semiconductor plane and the temperature regulating element in the first direction and also between the semiconductor plane and the thermal plane in a second direction crossing the first direction.

3. The optical transmission module according to claim 2, wherein the dielectric block has a first distance between the semiconductor plane and the thermal plane in the second direction, the first distance being equal to or larger than 450 micrometers.

4. The optical transmission module according to claim 2, wherein the dielectric block has a second distance between the semiconductor plane and the temperature regulating element in the first direction, the second distance being equal to or larger than 450 micrometers.

5. The optical transmission module according to claim 1, wherein
the signal terminal is configured to receive an electrical signal,
the optical semiconductor element is configured to emit an optical signal along the first direction in accordance with the electrical signal,
the lens is configured to collimate the optical signal, and
the semiconductor plane and the optical plane are parallel with each other.

6. The optical transmission module according to claim 1, further comprising:
a temperature sensing element mounted on the semiconductor plane, the temperature sensing element being configured to measure a temperature of the optical semiconductor element.

7. The optical transmission module according to claim 1, wherein the dielectric substance is ceramic.

8. The optical transmission module according to claim 1, further comprising:
a board which extends along the first direction, the board being electrically connected to the signal terminal,
wherein the optical semiconductor element is electrically connected to the board, and the semiconductor plane includes a transmission line electrically connected to the optical semiconductor element.
